(19) United States
(12) Patent Application Publication
(10) Pub. No.: US 2026/0029472 A1
(43) Pub. Date: Jan. 29, 2026

(54) MODEL-INPUT-BASED CALIBRATION FOR BATTERY STATE ESTIMATION

(71) Applicant: Analog Devices, Inc., Wilmington, MA (US)

(72) Inventors: Frank M. Yaul, Cambridge, MA (US); Surya Teja Chavali, Freemant, CA (US); Omer Tanovic, Acton, MA (US)

(21) Appl. No.: 19/256,684

(22) Filed: Jul. 1, 2025

Related U.S. Application Data
(60) Provisional application No. 63/674,569, filed on Jul. 23, 2024.

(51) Int. Cl. G01R 31/367; G01R 31/00; G01R 31/389; G01R 35/00

(52) U.S. Cl. CPC G01R 31/367; G01R 31/389; G01R 35/005; G01R 31/007

(57) ABSTRACT

Techniques for estimating a battery state of a battery include receiving a present battery measurement associated with an unknown battery state and a calibration measurement associated with a known calibration condition. An input set is generated based on the present battery measurement and the calibration measurement. The input set is inputted into a battery state model to receive an output of the battery state model. The output includes a present battery state estimation for the unknown battery state.

### CLAIMS OF PRIORITY

This patent application claims the benefit of priority U.S. Provisional Patent Application Ser. No. 63/674,569, titled “MODEL-INPUT-BASED CALIBRATION FOR BATTERY STATE ESTIMATION,” filed on Jul. 23, 2024, which is hereby incorporated by reference herein in its entirety.

### TECHNICAL FIELD

The present disclosure generally relates to a model-input-based calibration method and system for improving the performance of a machine learning regression model for estimating battery states.

### BACKGROUND

Rechargeable batteries, such as lithium-ion batteries, are commonly used for portable electronics and electric vehicles (EVs), as well as a variety of other applications, such as military and aerospace applications. It is important to monitor the battery state, such as temperature, of such batteries to maximize the performance of the batteries. Accurate assessment of battery states, such as internal temperature, can play a significant role in optimizing performance and ensuring safety.

Some conventional techniques for estimating battery states can involve performing a calibration using a large amount of measured data where the ground truth battery state is known, which can be impractical for real-world applications.

### SUMMARY

The present disclosure describes a method for estimating a battery state of a battery. The method includes receiving a present battery measurement associated with an unknown battery state; receiving a calibration measurement associated with a known calibration condition; generating an input set based on the present battery measurement and the calibration measurement; inputting the input set into a battery state model; and receiving an output of the battery state model, wherein the output includes a present battery state estimation for the unknown battery state.

The present disclosure also describes a system including at least one hardware processor and at least one memory storing instructions that, when executed by the at least one hardware processor, cause the at least one hardware processor to perform operations. The operations include receiving a present battery measurement associated with an unknown battery state; receiving a calibration measurement associated with a known calibration condition; generating an input set based on the present battery measurement and the calibration measurement; inputting the input set into a battery state model; and receiving an output of the battery state model, wherein the output includes a present battery state estimation for the unknown battery state.

The present disclosure further describes a machine-storage medium embodying instructions that, when executed by a machine, cause the machine to perform operations. The operations include receiving a present battery measurement associated with an unknown battery state; receiving a calibration measurement associated with a known calibration condition; generating an input set based on the present battery measurement and the calibration measurement; inputting the input set into a battery state model; and receiving an output of the battery state model, wherein the output includes a present battery state estimation for the unknown battery state.

### BRIEF DESCRIPTION OF THE DRAWINGS

Various ones of the appended drawings merely illustrate example embodiments of the present disclosure and should not be considered as limiting its scope.

FIGS. 1A-1B illustrate model for estimating the internal temperature of a battery.

FIG. 2 is a flow diagram of a method for training a model using a model-input-based calibration technique.

FIG. 3 is a flow diagram of a method 300 for estimating battery state in a normal operation mode using a model-input-based calibration technique.

FIG. 4 is a simplified block diagram of a training framework using a model-input-based calibration technique.

FIG. 5 is a simplified block diagram of an inference framework using a model-input-based calibration technique.

FIG. 6 shows an example input vector for normal operation mode.

FIG. 7 shows an example input vector for normal operation mode.

FIG. 8 is a simplified block diagram of an inference framework using a model-input-based calibration technique and a linearized model.

FIG. 9 is a simplified block diagram of a multiple model system.

FIG. 10 illustrates a block diagram of an example comprising a machine upon which any one or more of the techniques (e.g., methodologies) discussed herein may be performed.

### DETAILED DESCRIPTION

As noted above, it is important to monitor battery states, such as the internal temperature, of rechargeable batteries, such as lithium-ion batteries, to monitor and maximize the performance of such batteries. For larger batteries, such as electric vehicle (EV) batteries, the internal temperature of the battery has previously been monitored using thermal sensors, such as thermocouples, placed on the surface of the battery to monitor the surface temperature of the battery. This solution is non-ideal due to the delay in heat conductivity from the battery's internal core to the surface temperature, as well as the cost and complexity of implementing the necessary thermocouple network in connection with the battery.

Some measurement techniques can employ a machine learning (ML) model to estimate internal temperature of batteries. For example, a regression model may be trained to estimate battery temperature based on present input. However, it can be challenging for a regression model to handle cell-to-cell variation and changes to the nonlinear, multivariate electrochemical impedance spectroscopy (EIS)/temperature relationship as the battery ages. A calibration algorithm can be used to handle these challenges.

However, to be practical, calibration data should be minimal and calibration data measurement should not use substantial time or energy. Also, the calibration technique should extrapolate from the small amount of calibration data to improve accuracy across the range of operating conditions. Extrapolating from a minimal set of calibration data is challenging for conventional fine-tuning calibration techniques used in ML, since there is a risk of overfitting the large number of model parameters to a relatively small amount of data.

The calibration techniques described herein introduce a model-input-based calibration method for improving the performance of machine learning models used in battery state estimation. The techniques leverage calibration measurements as input features to the model, allowing the model to learn from training data how to enhance estimates based on the calibration data. This approach only uses a small number of measurements from the battery cells when deployed in the field, making the calibration techniques practical.

Different types of models can be used battery state estimation. In some examples, a multivariable polynomial regression model may be used.

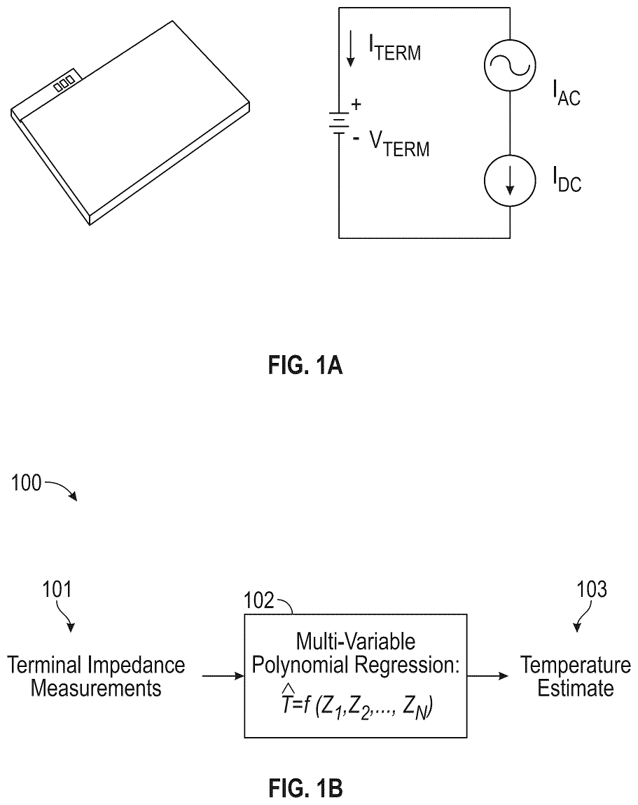

As generally illustrated in FIG. 1A, a multivariable polynomial regression is used to estimate the internal temperature of a battery (such as a lithium-ion battery) using terminal impedance measurements taken at multiple frequencies of an injected sinusoidal current. In some examples, the frequencies for use are identified based on a type of battery.

FIG. 1B illustrates a block diagram of a system 100 for using multivariable polynomial regression model to estimate the internal temperature of a battery from impedance measurements at multiple frequencies. As shown in FIG. 1B, terminal impedance measurements taken at a variety of frequencies (designated in FIG. 1B by a reference numeral 101) are input to a multivariable polynomial regression model 102, the output of which is an internal battery temperature estimate. However, this model may need to be calibrated with recent measurements from the target battery cell to provide accurate estimates.

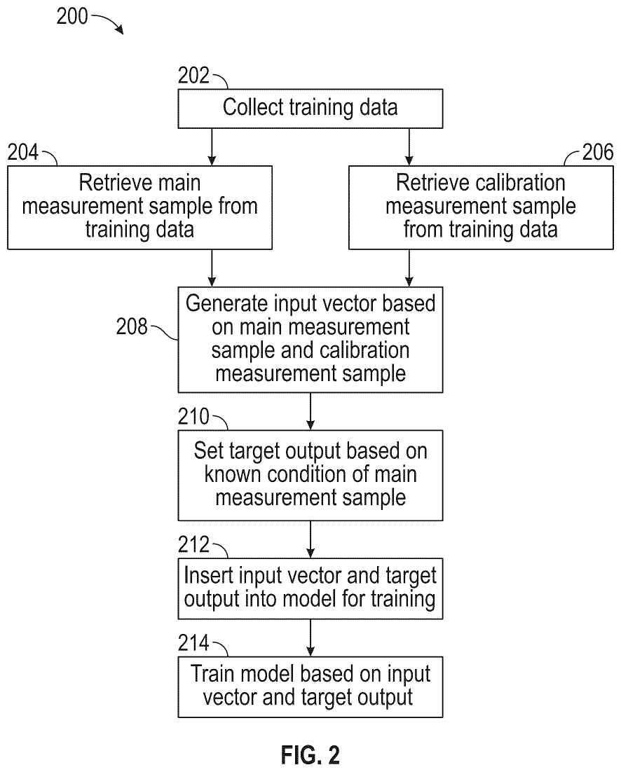

Next, a model-input-based calibration method to calibrate a model, such as model 102, is described. FIG. 2 is a flow diagram of a method 200 for training a model using a model-input-based calibration technique. In some examples, method 200 may be performed in a factory setting.

At operation 202, training data is collected. The training data may include measurement data at different temperatures. For example, the training data may include measurement data, such as impedance measurements, at different known temperatures. The training data can cover a range of state of charge (SoC) values, temperatures, aging, and different cells.

At operation 204, a main measurement sample is retrieved from the training data. The main measurement sample may include measurement data (MO), such as impedance measurements (e.g., EIS measurements), at a known condition, such as temperature (TO). The known condition may also include a SoC value.

At operation 206, a calibration measurement sample is retrieved from the training data. The calibration measurement sample may include measurements data (MCAL), such as impedance measurement, at a known calibration condition, such as temperature (TCAL). The known calibration condition may also include a SoC value. In some examples, a plurality of calibration measurement samples at different calibration conditions may be used. In some examples, both MCAL and MO may be drawn from the same pool of samples that form the training data. That is, main measurement samples and calibration measurement samples may be collected using the same training data collection procedure.

At operation 208, an input set, such as an input vector (M′), is generated based on the main measurement sample and calibration measurement sample. The input vector may include the measurement data (MO) from the main measurement sample and measurement data (MCAL) from the calibration measurement sample. In some examples, the input vector may also include the calibration condition, such as the temperature (TCAL) and/or SoC. In some examples, the input set may include a set of values, such as scalar values.

At operation 210, a target output of the model is set to the temperature (TO) of the main measurement sample.

At operation 212, the input vector and the target output are inputted into the model for training. At operation 214, the model performs operations to train the model so that the model output substantially matches the target output based the input vector. In some examples, the operations may include an iterative process. The model output of the battery state should substantially match the battery state information (TO) of the main measurement sample after training. The model learns how to use the calibration measurements to better estimate or predict the relationship between battery measurements and battery state, such as battery temperature.

For example, for some types of models, such as multivariable polynomial regression, the model may fit parameters using a linear algebra operation (e.g., linear least square operation). For example, the multivariable polynomial regression model may adjust its coefficients in the training process. For some more complex models, such as neural network models, the operations may include an iterative process to train different layers of the model.

Method 200 may use a training dataset with many different measurement values to train the model. The different measurements may be for different temperatures so that the model is trained for a wide variety of temperatures.

After the model is trained, the model may be deployed. For example, the model may be deployed in an EV in normal operation mode to estimate battery state.

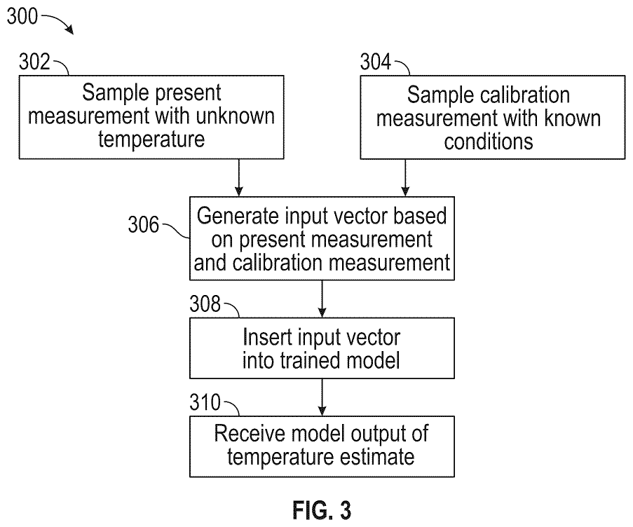

FIG. 3 is a flow diagram of a method 300 for estimating battery state in a normal operation mode (inference mode) using a model-input-based calibration technique. For example, method 300 may be performed in an EV in which the trained mode has been deployed.

At operation 302, a present/current measurement (main measurement) may be sampled. For example, the present measurement may include an impedance measurement (X0). In some examples, the present measurement may also include the SoC. The present temperature (TO) is unknown and is to be estimated with method 300.

At operation 304, a calibration measurement may be sampled or retrieved. The calibration measurement may include an impedance measurement (X1) and a known calibration condition, such as temperature (T1). The calibration measurement may have been taken in normal operation mode prior to the present time. For example, calibration measurements may be updated every 1-2 weeks in normal operation mode. In some examples, a plurality calibration measurement samples at different calibration temperatures may be used.

At operation 306, an input set, such as an input vector (M′), is generated based on the present measurement sample and calibration measurement sample. The input vector may include the impedance measurement (X0) from the main measurement sample and impedance measurement (X1) from the calibration measurement sample. In some examples, the input vector may also include the calibration temperature (T1), which is known. In some examples, the input set may include a set of values, such as scalar values.

At operation 308, the input vector is inputted into the trained model. The components of the input vector including the impedance measurements of the main measurement sample and the calibration measurement, as well as the calibration temperature, may be treated as normal regressors of the model. At operation 310, the model may perform operations based on the input vector to generate an estimate of the battery state, such as temperature (T0), for the present measurement (X0). The model output of the temperature estimate is received. The EV may then use the temperature estimate (T0) to adjust battery and vehicle operations.

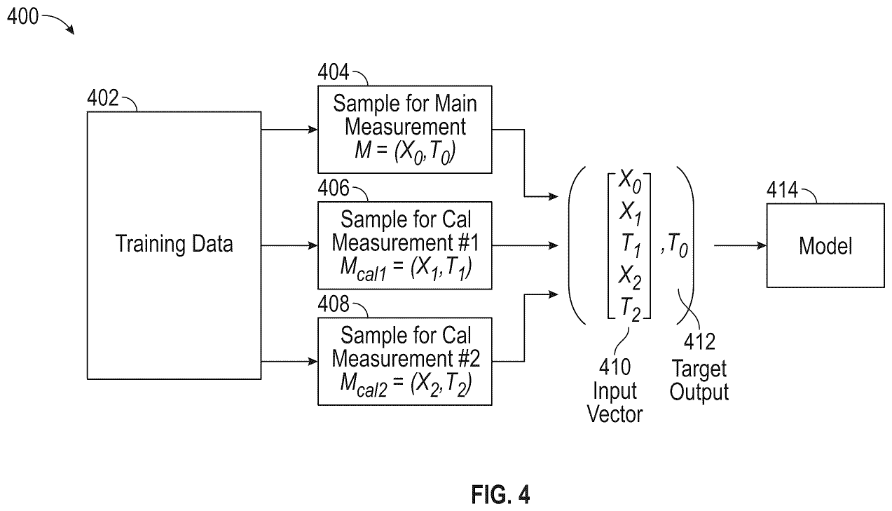

As mentioned above, a plurality of calibration measurements may be used in training and normal operation mode. FIG. 4 is a simplified block diagram of a training framework 400 using a model-input-based calibration technique. The training framework 400 includes training data 402. The training data 402 may be stored in one or more databases. The training data 402 may include a plurality of samples where each sample may include measurement data and the corresponding known conditions, such as temperature, for when the measurement data was collected. The measurement data may include impedance measurements, SoC, etc.

Main measurement sample 404 may be retrieved from the training data 402. The main measurement sample 404 may include measurement data (X0) and the corresponding known temperature (T0).

Calibration sample 406 may be retrieved from the training data. The calibration sample 406 may include measurement data (X1) and the corresponding known temperature (T1).

Calibration sample 408 may be retrieved from the training data. The calibration sample 408 may include measurement data (X2) and the corresponding known temperature (T2). T1 and T2 may be different known temperatures. For example, T1 may be 25° and T2 may be 40°.

An input vector 410 is generated based on the main measurement sample 404, calibration sample 406, and calibration sample 408. For example, the input vector 410 may include measurement data (X0) from the main measurement sample 404, measurement data (X1) and calibration temperature (T1) from the calibration sample 406, and measurement data (X2) and calibration temperature (T2) from the calibration sample 408.

A target output 412 may set as the temperature (T0) from the main measurement sample 404. The input vector 410 and target output 412 may be inputted into a model 414. The model 414 may include a machine learning model, such as a multivariable polynomial regression model. The model 414 may perform a training process. The model 414 may perform operations to train the model 414 so that the output of the model 414 substantially matches the target output 412 based the input vector 410, as described above. For example, the coefficients of the multivariable polynomial regression model may be adjusted in the training process. The training process may be performed with a plurality of main measurement samples and corresponding calibration measurement samples (e.g., linear least square fitting).

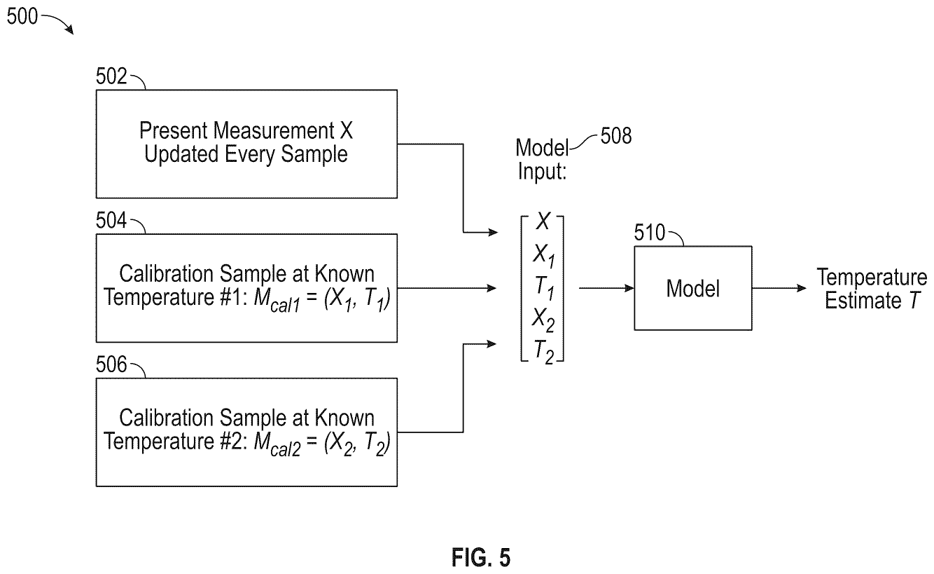

FIG. 5 is a simplified block diagram of an inference framework 500 using a model-input-based calibration technique. The inference framework 500 may be deployed to be used in normal operation mode (inference mode).

Present measurement 502 (X) may be sampled at the current time. The present measurement 502 may be updated every sample. For example, the present measurement 502 may include an impedance measurement at an unknown temperature (T) to be estimated.

A calibration sample 504 may be sampled during normal operation mode. For example, the calibration sample 504 may be updated every 1-2 weeks in normal operation mode. The calibration sample 504 may include a measurement data (X1) and a known calibration condition, such as temperature (T1), when the measurement data (X1) was taken.

A calibration sample 506 may be sampled during normal operation mode. For example, the calibration sample 506 may be updated every 1-2 weeks in normal operation mode. The calibration sample 504 may include a measurement data (X2) and a known calibration condition, such as temperature (T2), when the measurement data (X2) was taken. T2 for calibration sample 506 maybe a different temperature than T1 for calibration sample 504.

A model input 508 may be generated from the present measurement 502, calibration sample 504, and calibration sample 506. For example, the model input 508 may include measurement data (X) from the present measurement 502, measurement data (X1) and temperature (T1) from the calibration sample 504, and measurement data (X2) and temperature (T2) from the calibration sample 506.

The model 510 may receive the model input 508. The model 510 may correspond to the trained model using the training framework 400, as described above. For example, the model 510 may be deployed in an EV to operate in normal operation mode. The model 510 may generate a temperature estimate output (T) based on the model input 508, which corresponds to the battery temperature for the current time.

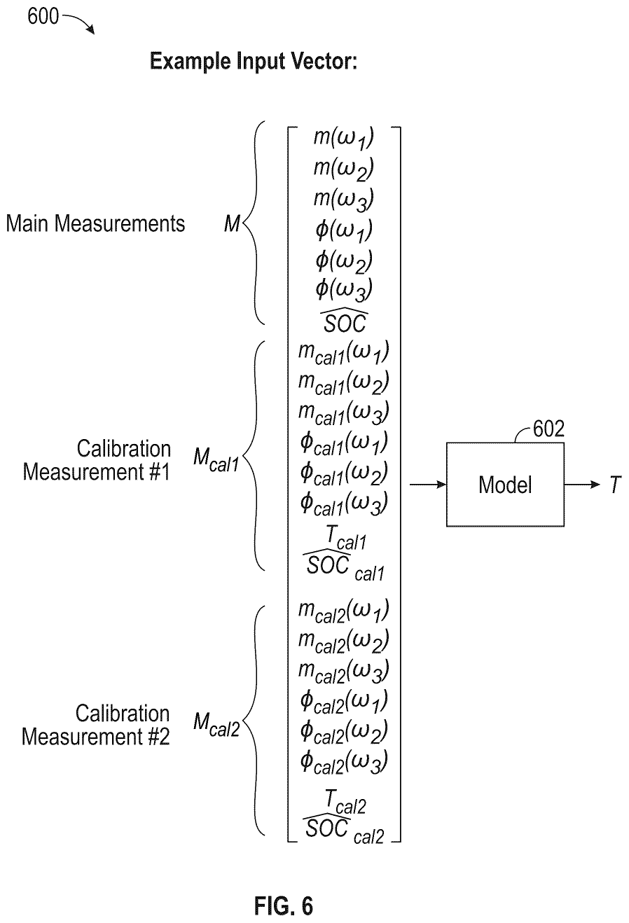

As noted above, measurement data may include measured battery parameters such as impedance measurements, SoC, etc. Estimates of battery parameters, such as an estimate of the SoC, may also be used. For example, the estimate can be used when a direct measurement of the parameter is not available. FIG. 6 shows an example input vector 600 for normal operation mode. FIG. 6 shows a main measurement M taken at unknown temperature T to be estimated. The main measurement M includes a plurality of impedance magnitude values (m(ω₁), m(ω₂), m(ω₃)), a plurality of impedance phase values (ϕ(ω₁), ϕ(ω₂), ϕ(ω₃)), and estimated [symbol] .

First calibration measurement (M_{cal1}) includes impedance magnitude values (m_{cal1} (ω₁), m_{cal1} (ω₂), m_{cal1} (ω₃),), a plurality of impedance phase values (ϕ_{cal1}(ω₁), ϕ_{cal1}(ω₂), ϕ_{cal1}(ω₃)), and estimated [symbol] taken at a known first calibration temperature. The input vector may also include the first known calibration temperature (T_{cal1}).

Second calibration measurement (M_{cal2}) includes impedance magnitude values (m_{cal2}(ω₁), m_{cal2}(ω₂), m_{cal2}(ω₃),), a plurality of impedance phase values (ϕ_{cal2}(ω₁), ϕ_{cal2}(ω₂), ϕ_{cal2}(ω₃)), and estimated [symbol] taken at a known second calibration temperature. The input vector may also include the second known calibration temperature (T_{cal2}).

The input vector is inputted into model 602 to generate a battery estimate T, which corresponds to the battery temperature for the main measurement. As mentioned herein, calibration techniques can involve a target SOC in addition to a target temperature.

In the FIG. 6 example, the known calibration temperatures (T_{cal1}, T_{cal2}) are included in the input vector 600. However, in some examples, the calibration measurements may be taken at specified (nominal) temperatures (and/or SoCs) within a tolerance threshold so that the calibration temperature values are not included in the input vector. For example, the first calibration measurement may be taken at a first specified temperature (e.g., 25°±2° each time and the second calibration measurement may be taken at a second specified temperature (e.g., 40°±2° each time. In this example, the calibration temperatures (and/or SoCs) may not be included in the input vector since the model is trained and used with calibration measurements at the specified temperatures (and/or SoCs) thereby reducing the number of dimensions of the input vector and reducing computational workload.

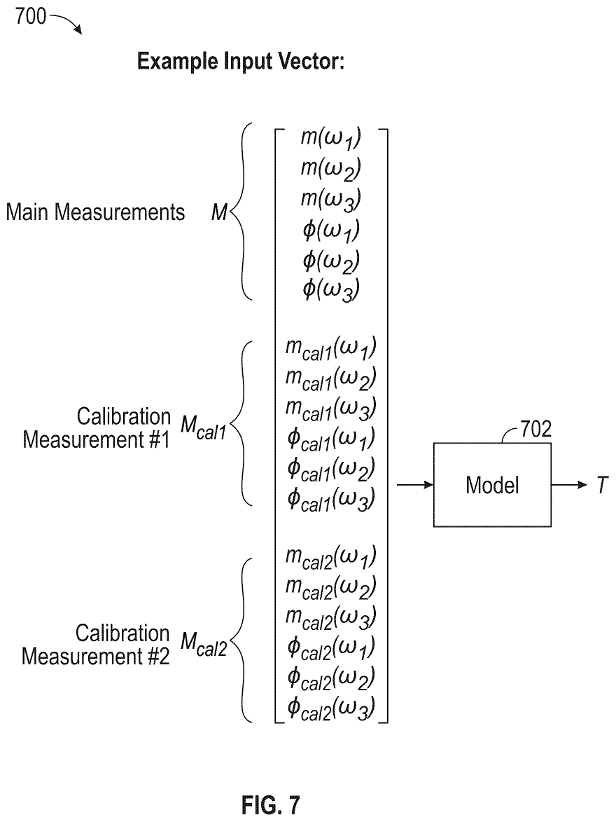

FIG. 7 shows an example input vector without calibration temperature values or SoC values for normal operation mode. FIG. 7 shows a main measurement M taken at unknown temperature T to be estimated. The main measurement M includes a plurality of impedance magnitude values (m(ω₁), m(ω₂), m(ω₃)) and a plurality of impedance phase values (ϕ(ω₁), ϕ(ω₂), ϕ(ω₃)).

First calibration measurement (M_{cal1}) includes impedance magnitude values (m_{cal1} (ω₁), m_{cal1} (ω₂), m_{cal1} (ω₃),) and a plurality of impedance phase values (ϕ_{cal1}(ω₁), ϕ_{cal1}(ω₂), ϕ_{cal1}(ω₃)) taken at a known first calibration temperature. In this example, the known first calibration temperature is a specified temperature value where the first calibration measurement is taken each time. For example, the first calibration measurement may be taken at 25°±2° each time (e.g., updated every 1-2 weeks). Consequently, the input vector may not include the first calibration temperature or SoC values, reducing the number of dimensions in the input vector.

Second calibration measurement (M_{cal2}) includes impedance magnitude values (m_{cal2}(ω₁), m_{cal2}(ω₂), m_{cal2}(ω₃),) and a plurality of impedance phase values (ϕ_{cal2}(ω₁), ϕ_{cal2}(ω₂), ϕ_{cal2}(ω₃)) taken at a known calibration temperature. In this example, the known second calibration temperature is a specified temperature value where the second calibration measurement is taken each time. For example, the second calibration measurement may be taken at 40°±2° each time (e.g., updated every 1-2 weeks). Consequently, the input vector may not include the second calibration temperature or SoC values, reducing the number of dimensions in the input vector.

The input vector is inputted into model 702 to generate a battery estimate T, which corresponds to the battery temperature for the main measurement.

In some scenarios, sampling the calibration values at the specified calibration temperatures may be difficult to obtain during normal operation mode. In these scenarios, calibration measurements may be sampled near the specified calibration temperatures, but outside the tolerance threshold. A linearized model may then be used to estimate the calibration measurement value at the specified calibration temperature based on the measurements taken at the temperature outside the tolerance threshold. The linearized model may therefore widen the calibration tolerance range while maintaining the reduction of dimensions of the input vector by using calibration measurements at specified calibration temperatures.

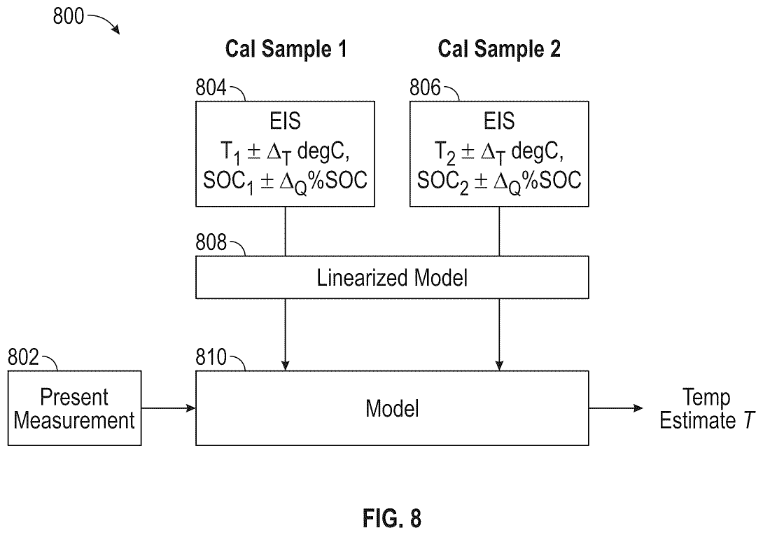

FIG. 8 is a simplified block diagram of an inference framework 800 using a model-input-based calibration technique and a linearized model.

Present measurement 802 (X) may be sampled at the current time. The present measurement 802 may be updated every sample. For example, the present measurement 802 may include an impedance measurement at an unknown temperature (T) to be estimated.

A calibration sample 804 may be sampled during normal operation mode. For example, the calibration sample 804 may be updated every 1-2 weeks in normal operation mode. The calibration sample 804 may include a measurement data (X1) and a known calibration temperature (T1) when the measurement data (X1) was taken. However, calibration temperature T1 may be outside the tolerance range for the specified first calibration conditions, such as temperature and SoC. For example, if the specified first calibration temperature is set to 25°±2°, the calibration temperature T1 may be outside of that range, say 30°.

Likewise, a calibration sample 806 may be sampled during normal operation mode. For example, the calibration sample 806 may be updated every 1-2 weeks in normal operation mode. The calibration sample 806 may include a measurement data (X2) and a known calibration temperature (T2) when the measurement data (X2) was taken. However, calibration temperature T2 may be outside the tolerance range for the specified second calibration conditions, such as temperature and Soc. For example, if the specified second calibration temperature is set to 40°±2°, the calibration temperature T1 may be outside the range, say 37°.

A linearized model 808 may receive the calibration sample 804 and calibration sample 806 and generate calibration measurement estimates at the specified calibration temperatures at which the model 810 was trained. The linearized model may compensate for tolerances. In some examples, the linearized model may include Taylor approximation that allows the linearized model 808 to estimate the calibration measurements would have been at the specified calibration temperatures. For example, consider a specified calibration condition of 20° and 70% SoC. However, the calibration measurement was taken at 23° and 74% SoC, which is outside the tolerance range. The linearized model 808 may generate an estimated calibration measurement at the specified calibration condition of 20° and 70% SoC based on the calibration measurement taken at 23° and 74% SoC.

In some examples, a forward EIS model may be used. The forward EIS model enables widening the range of allowed calibration conditions. The forward EIS model may map from battery state information, such as temperature and SOC, to EIS measurements. The forward EIS model may be linearized around the calibration condition operating points. For example, the linear model 808 may be obtained by linearizing the forward EIS model around the calibration condition operating points. Using the linearized EIS model allows wider tolerances for calibration conditions (e.g. ±Δ_{T} degC, ±Δ_{Q}% SOC).

As described above, some calibration measurements may be taken very close to a specified “nominal” temperature T and SoC. Using the forward EIS model, the system may compute a Taylor expansion approximation at a particular (T, SOC) operating point:

mₖ(T+ΔT,SOC+ΔSOC)

$${{\approx {m}_{k} ( T , SOC ) + \frac{\partial {m}_{k}}{\partial T} \vert}_{T , SOC} \cdot Δ T + \frac{\partial {m}_{k}}{\partial SOC} \vert}_{T , SOC} \cdot Δ SOC$$

Thus, if there is a calibration measurement at [T+ΔT, SOC+ΔSOC], the system can estimate what the measurement would have been at [T, SOC] by using the Taylor expansion.

There are different techniques for performing this estimate. For example, one technique is to Taylor expand at [T+ΔT, SOC+ΔSOC]. The system can compute the partial derivative at different operating points:

$${{m}_{k} ( T , SOC ) \approx {m}_{k} ( T + Δ T , SOC + Δ SOC ) - \frac{\partial {m}_{k}}{\partial T} \vert}_{T + Δ T , SOC + Δ S O C} \cdot Δ T {- \frac{\partial {m}_{k}}{\partial SOC} \vert}_{T + Δ T , SOC , Δ SOC} \cdot Δ SOC$$

Another simpler technique allows the system to compute the partial derivatives at the nominal (T, SOC) which is fixed:

$${{{m}_{k} ( T , SOC ) \approx {m}_{k} ( T + Δ T , SOC + Δ SOC ) - \frac{\partial {m}_{k}}{\partial T} \vert}_{T , SOC} \cdot Δ T - \frac{\partial {m}_{k}}{\partial S O C} \vert}_{T , SOC} \cdot Δ SOC$$

By being able to “normalize” the calibration EIS measurement at [T+ΔT, SOC+ΔSOC] and estimate what it would have been at [T, SOC], system can now use the estimate just like a normal calibration measurement. This approach widens the temperature and SOC range of valid calibration measurements that can be used.

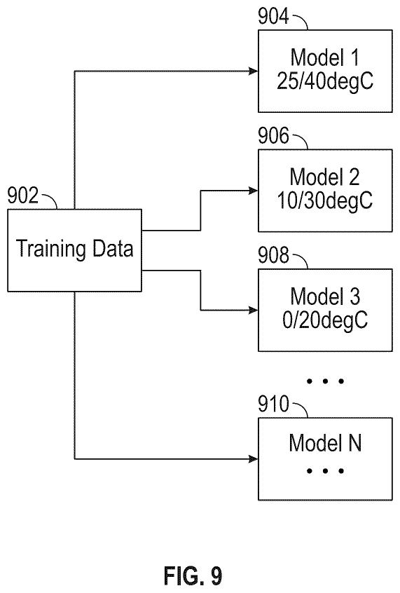

In some examples, multiple models trained for different calibration conditions (e.g., temperature, SOC) may be used. FIG. 9 is a simplified block diagram of a multiple model system. In this example, each model is trained for two temperature calibration condition. Training data 902 may be stored in one or more databases. The training data 902 may include a plurality of samples where each sample may include measurement data and the corresponding known temperature for when the measurement data was collected. The measurement data may include impedance measurements, SoC, etc.

The training data may be used to train models 904-910. Each model may be trained to receive calibration inputs at different conditions, such as calibration temperature and/or SoC. For example, model 904 may be programmed to receive as inputs calibration measurements at the specified temperature of 25° and 40°. Model 906 may be programmed to receive as inputs calibration measurements at the specified temperature of 10° and 30°. Model 908 may be programmed to receive as inputs calibration measurements at the specified temperature of 0° and 20°, and so on for model 910 (Model N).

The plurality of models 904-910 may be deployed in the EV to be used in normal operation mode. During inference mode, the system may select which model to use based on the temperatures of recent calibration measurements. For example, for an EV in a cold environment, the recent calibration measurements may indicate that model 908 (0° and) 20° may be more appropriate to use as compared to model 904 (25° and) 40°, which is better suited for warmer conditions.

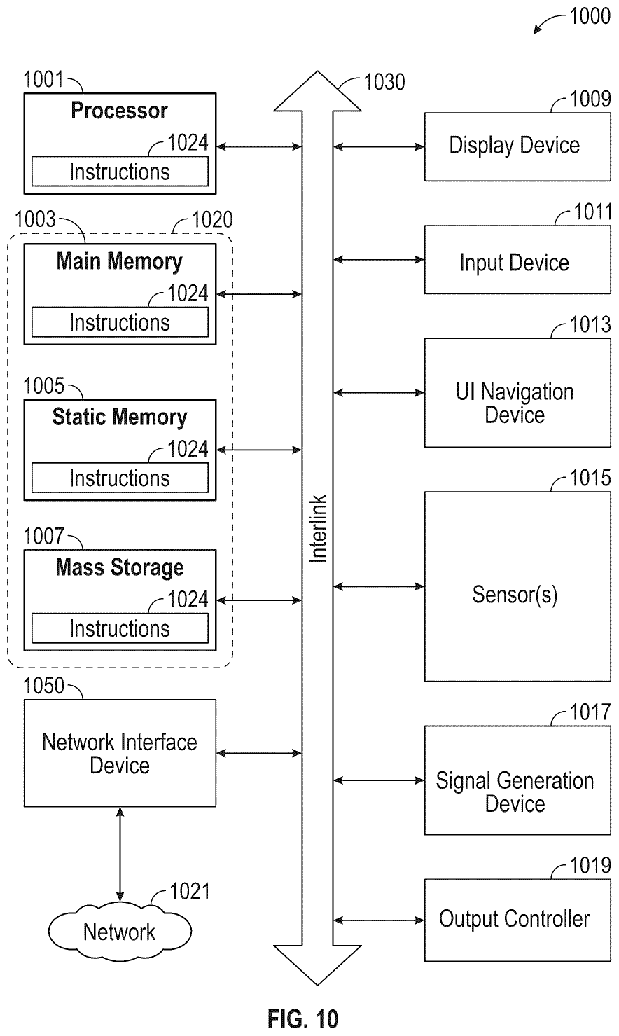

The techniques shown and described in this document can be performed using a portion or an entirety of battery monitoring system as described above or otherwise using a machine 1000 as discussed below in relation to FIG. 10. FIG. 10 illustrates a block diagram of an example comprising a machine 1000 upon which any one or more of the techniques (e.g., methodologies) discussed herein may be performed. In various examples, the machine 1000 may operate as a standalone device or may be connected (e.g., networked) to other machines.

In a networked deployment, the machine 1000 may operate in the capacity of a server machine, a client machine, or both in server-client network environments. In an example, the machine 1000 may act as a peer machine in peer-to-peer (P2P) (or other distributed) network environment. The machine 1000 may be a personal computer (PC), a tablet device, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic or a number of components, or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware comprising the circuitry may include variably connected physical components (e.g., execution units, transistors, simple circuits, etc.) including a computer-readable medium physically modified (e.g., magnetically, electrically, such as via a change in physical state or transformation of another physical characteristic, etc.) to encode instructions of the specific operation. In connecting the physical components, the underlying electrical properties of a hardware constituent may be changed, for example, from an insulating characteristic to a conductive characteristic or vice versa. The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine 1000 (e.g., computer system) may include a hardware-based processor 1001 (e.g., a central processing unit (CPU), a graphics processing unit (GPU), a hardware processor core, or any combination thereof), a main memory 1003 and a static memory 1005, some or all of which may communicate with each other via an interlink 1030 (e.g., a bus). The machine 1000 may further include a display device 1009, an input device 1011 (e.g., an alphanumeric keyboard), and a user interface (UI) navigation device 1013 (e.g., a mouse). In an example, the display device 1009, the input device 1011, and the UI navigation device 1013 may comprise at least portions of a touch screen display. The machine 1000 may additionally include a storage device 1020 (e.g., a drive unit), a signal generation device 1017 (e.g., a speaker), a network interface device 1050, and one or more sensors 1015, such as a global positioning system (GPS) sensor, compass, accelerometer, or other sensor. The machine 1000 may include an output controller 1019, such as a serial controller or interface (e.g., a universal serial bus (USB)), a parallel controller or interface, or other wired or wireless (e.g., infrared (IR) controllers or interfaces, near field communication (NFC), etc., coupled to communicate or control one or more peripheral devices (e.g., a printer, a card reader, etc.).

The storage device 1020 may include a machine readable medium on which is stored one or more sets of data structures or instructions 1024 (e.g., software or firmware) embodying or utilized by any one or more of the techniques or functions described herein. The instructions 1024 may also reside, completely or at least partially, within a main memory 1003, within a static memory 1005, within a mass storage device 1007, or within the hardware-based processor 1001 during execution thereof by the machine 1000. In an example, one or any combination of the hardware-based processor 1001, the main memory 1003, the static memory 1005, or the storage device 1020 may constitute machine readable media.

While the machine readable medium is considered as a single medium, the term “machine readable medium” may include a single medium or multiple media (e.g., a centralized or distributed database, and/or associated caches and servers) configured to store the one or more instructions 1024.

The term “machine readable medium” may include any medium that is capable of storing, encoding, or carrying instructions for execution by the machine 1000 and that cause the machine 1000 to perform any one or more of the techniques of the present disclosure, or that is capable of storing, encoding or carrying data structures used by or associated with such instructions. Non-limiting machine-readable medium examples may include solid-state memories, and optical and magnetic media. Accordingly, machine-readable media are not transitory propagating signals. Specific examples of massed machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic or other phase-change or state-change memory circuits; magnetic disks, such as internal hard disks and removable disks; magneto-optical disks; and CD-ROM and DVD-ROM disks.

The instructions 1024 may further be transmitted or received over a communications network 1021 using a transmission medium via the network interface device 1050 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., the Institute of Electrical and Electronics Engineers (IEEE) 802.22 family of standards known as Wi-Fi®, the IEEE 802.26 family of standards known as WiMax®), the IEEE 802.27.4 family of standards, peer-to-peer (P2P) networks, among others. In an example, the network interface device 1050 may include one or more physical jacks (e.g., Ethernet, coaxial, or phone jacks) or one or more antennas to connect to the communications network 1021. In an example, the network interface device 1050 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 1000, and includes digital or analog communications signals or other intangible medium to facilitate communication of such software.

### Various Notes

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific implementations in which the invention can be practiced. These implementations are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other implementations can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed implementation. Thus, the following claims are hereby incorporated into the Detailed Description as examples or implementations, with each claim standing on its own as a separate implementation, and it is contemplated that such implementations can be combined with each other in various combinations or permutations. The scope of the invention should be determined with reference to the appended claims, along with the full scope of equivalents to which such claims are entitled.

1. A method for estimating a battery state of a battery, the method comprising:
receiving a present battery measurement associated with an unknown battery state;
receiving a calibration measurement associated with a known calibration condition;
generating an input set based on the present battery measurement and the calibration measurement;
inputting the input set into a battery state model; and
receiving an output of the battery state model, wherein the output includes a present battery state estimation for the unknown battery state.

2. The method of claim 1, wherein the input set includes the known calibration condition.

3. The method of claim 1, wherein the present battery state estimation includes a temperature estimate for the battery.

4. The method of claim 1, wherein present battery measurement includes one or more impedance measurements.

5. The method of claim 4, wherein the one or more impedance measurements are taken at different frequencies.

6. The method of claim 1, wherein the known calibration condition includes a known calibration temperature.

7. The method of claim 6, wherein the known calibration condition further includes a known state of charge.

8. The method of claim 1, wherein battery state model includes a multivariable polynomial regression model.

9. The method of claim 1, wherein the calibration measurement is a first calibration measurement, and the known calibration condition is a first known calibration condition, the method further comprising:
receiving a second calibration measurement taken at a second known calibration condition,
wherein the input set is generated based on the present battery measurement and the first calibration measurement and the second calibration measurement.

10. The method of claim 1, wherein the known calibration condition is a target calibration condition; the method further comprising:
receiving a present calibration measurement at a present calibration condition, wherein the present calibration condition is outside a tolerance range of the target calibration condition;
applying a linearized model to the present calibration measurement to generate the calibration measurement at the target calibration condition.

11. A system comprising:
at least one hardware processor; and
at least one memory storing instructions that, when executed by the at least one hardware processor, cause the at least one hardware processor to perform operations comprising:
receiving a present battery measurement associated with an unknown battery state;
receiving a calibration measurement associated with a known calibration condition;
generating an input set based on the present battery measurement and the calibration measurement;
inputting the input set into a battery state model; and
receiving an output of the battery state model, wherein the output includes a present battery state estimation for the unknown battery state.

12. The system of claim 11, wherein the input set includes the known calibration condition.

13. The system of claim 11, wherein the present battery state estimation includes a temperature estimate for the battery.

14. The system of claim 11, wherein present battery measurement includes one or more impedance measurements taken at different frequencies.

15. The system of claim 11, wherein the known calibration condition includes a known calibration temperature.

16. The system of claim 15, wherein the known calibration condition further includes a known state of charge.

17. The system of claim 11, wherein battery state model includes a multivariable polynomial regression model.

18. The system of claim 11, wherein the calibration measurement is a first calibration measurement, and the known calibration condition is a first known calibration condition, the operations further comprising:
receiving a second calibration measurement taken at a second known calibration condition,
wherein the input set is generated based on the present battery measurement and the first calibration measurement and the second calibration measurement.

19. The system of claim 11, wherein the known calibration condition is a target calibration condition; the operations further comprising:
receiving a present calibration measurement at a present calibration condition, wherein the present calibration condition is outside a tolerance range of the target calibration condition;
applying a linearized model to the present calibration measurement to generate the calibration measurement at the target calibration condition.

20. A machine-storage medium embodying instructions that, when executed by a machine, cause the machine to perform operations comprising:
receiving a present battery measurement associated with an unknown battery state;
receiving a calibration measurement associated with a known calibration condition;
generating an input set based on the present battery measurement and the calibration measurement;
inputting the input set into a battery state model; and receiving an output of the battery state model, wherein the output includes a present battery state estimation for the unknown battery state.
